(19) United States
(12) Patent Application Publication
(10) Pub. No.: US 2016/0093789 A1
(43) Pub. Date: Mar. 31, 2016

(54) THERMOELECTRIC GENERATOR, IN PARTICULAR FOR A MOTOR VEHICLE

(71) Applicant: Thomas Himmer, Reichenbach (DE)

(72) Inventor: Thomas Himmer, Reichenbach (DE)

(73) Assignee: Mahle International GmbH, Stuttgart (DE)

(21) Appl. No.: 14/869,247

(22) Filed: Sep. 29, 2015

(30) Foreign Application Priority Data
Sep. 30, 2014 (DE) 102014219852.6

(51) Int. Cl. H01L 35/32; H01L 35/34

(52) U.S. Cl. CPC H01L 35/32; H01L 35/34

(57) ABSTRACT

A thermoelectric generator may include a housing that delimits a housing interior and has a first housing wall and a second housing wall opposite the first housing wall. The generator may also include a plurality of thermoelectric elements, each having a thermoelectrically active material and being arranged spaced apart from one another in the housing interior, wherein at least two adjacent thermoelectric elements are connected to one another by at least one conductor link. The conductor link may be fitted by at least one of a first electrical insulation on an inner side of the first housing wall facing the housing interior, and a second electrical insulation on an inner side of the second housing wall facing the housing interior. Each of the first and the second electrical insulation may include at least one graphite film and at least one carrier film having an electrically insulating material.

### CROSS-REFERENCE TO RELATED APPLICATIONS

This application claims priority to German Patent Application No. 10 2014 219 852.6, filed Sep. 30, 2014, the contents of which are hereby incorporated by reference in their entirety.

### TECHNICAL FIELD

The invention relates to a thermoelectric generator and to a method for producing such a thermoelectric generator.

### BACKGROUND

The term “thermoelectricity” is understood to mean the mutual influencing of temperature and electricity and the conversion of one into the other. Thermoelectric materials make use of this influence in order to generate electrical energy out of waste heat, as thermoelectric generators, that are also used in the form of so-called heat pumps when heat is intended to be transported from a thermal reservoir with a relatively low temperature into a thermal reservoir with a relatively high temperature with a consumption of electrical energy.

In motor vehicles having an internal combustion engine, thermoelectric generators can convert the waste heat generated during the combustion process in the exhaust gas partially into electrical energy and feed this electrical energy into the vehicle electrical distribution system of the motor vehicle. This waste heat converted into electrical energy can therefore be made useful for decreasing the energy consumption of the motor vehicle to a minimum extent that is functionally necessary and to avoid unnecessary emissions of waste gases such as CO₂, for example.

The application areas of thermoelectric generators in automotive engineering are therefore varied. It is of critical importance in any possible application scenario to achieve a high degree of efficiency in order to convert heat as effectively as possible into electrical energy. The use in motor vehicles furthermore results in the additional requirement for producing thermoelectric apparatuses with a compact design. Thermoelectric apparatuses installed in vehicles are therefore often produced with a plate-shaped or layered construction, wherein the thermoelectrically active elements are arranged within a thermally conductive housing. The housing can be thermally connected firstly to a thermal reservoir having a low temperature, the so-called cold side, but secondly also to a thermal reservoir having a higher temperature, namely the hot side, so that the thermoelectric elements generate a thermoelectric e.m.f. owing to the temperature drop between the two sides, which thermoelectric e.m.f. can be passed to the outside via suitable electrical terminals. The greater the temperature difference between the hot and cold sides, the higher the thermoelectric e.m.f. generated by the apparatus.

Typically, a thermoelectric apparatus comprises a plurality of thermoelectric elements consisting of thermoelectrically active materials, which are connected to one another via suitable electrical conductor links in the sense of an electrical series circuit. A single electrical conductor link in this case in particular connects two adjacent thermoelectric elements.

A permanent cohesive connection to one another in the context with thermoelectric generators has proven to be problematic. This is because the materials used in the various components of the thermoelectric generator typically have different coefficients of thermal expansion, which can result in considerable thermomechanical stresses in the materials of the affected components in the event of temperature fluctuations occurring in operation-dependent fashion in the thermoelectric generator.

Against this background, DE 10 2012 208 295 A1 describes a thermoelectric module comprising a thermoelectric element, which is fitted on a housing element. A joint seam region which has been formed by pressing a joining material together is provided between the two elements. A diffusion barrier which is intended to prevent the undesired ingress of joining material into the thermoelectrically active material of the thermoelectric element can be provided on the thermoelectric element.

WO2011/159804 A2 discloses a thermoelectric apparatus comprising thermoelectrically active elements consisting of a skutterudite. The apparatus comprises a layer which acts as diffusion barrier and is arranged in the manner of a sandwich between the thermoelectrically active element and a metal layer provided for electrical contact-making In one variant, the metal layer can also be provided between the diffusion barrier and the thermoelectric element.

### SUMMARY

An object of the present invention consists in providing an improved embodiment of a thermoelectric apparatus in which the above-described problem is eliminated.

This object is achieved by the subject matter of the independent patent claims. Preferred embodiments are the subject matter of the dependent patent claims.

Therefore, the basic concept of the invention consists in joining the conductor links, connecting the thermoelectrically active elements, of the thermoelectric generator using films consisting of graphite to the metallic housing walls of the thermoelectric generator. Such fastening of the conductor links to the housing walls with the aid of graphite films constitutes a non-cohesive connection. In order to nevertheless ensure the highly effective thermal contact between the thermoelectric elements and the housing which is necessary for operation of the thermoelectric generator, the graphite film can be heated during application to the conductor links or the housing walls of the housing. In this way, the thermal resistance between the graphite film and the housing walls or the conductor links is minimized. Furthermore, the graphite film can act as thermomechanical interface, by means of which the thermomechanical stresses occurring between the conductor links and the housing walls owing to their different coefficients of thermal expansion can be largely or even completely avoided.

A thermoelectric generator according to the invention has a sufficiently dimensioned housing, preferably consisting of metal, which delimits a housing interior. The housing comprises a first housing wall and a second housing wall, which is opposite the first housing wall, wherein the two housing walls are thermally insulated from one another. As a result, the first housing wall can in a known manner act as hot side and the second housing wall can act as cold side of the thermoelectric generator, or vice versa. A plurality of thermoelectric elements is arranged spaced apart from one another in the housing interior, said thermoelectric elements comprising a thermoelectrically active material. The individual thermoelectric elements can be arranged equidistantly from one another along a longitudinal direction of the housing. With the exception of the two thermoelectric elements at the ends with respect to the longitudinal direction, each thermoelectric element is electrically connected, on its side facing the first housing wall, to the adjacent element in the longitudinal direction by means of a conductor link consisting of an electrically conductive material. The same thermoelectric element is electrically connected, on its side facing the second housing wall, to the element adjacent in the direction opposite the longitudinal direction by means of a further conductor link, or vice versa. It is clear that only one conductor link, to the only adjacent thermoelectric element, is required for the two end-side thermoelectric elements, which single conductor link is arranged either on the side facing the first housing wall or on the side assigned to the second housing wall.

In accordance with the invention, each of the conductor links is fitted either by means of an electrically insulating first electrical insulation on an inner side, facing the housing interior, of the first housing wall or by means of an electrically insulating second electrical insulation on an inner side, facing the housing interior, of the second housing wall. Both the first and the second electrical insulations in this case each comprise at least one graphite film.

An improved interface in terms of heat transmission and of avoiding thermoelectric e.m.f. between the housing walls and the conductor links can be achieved, in a preferred embodiment, by virtue of the first electrical insulation being provided in each case with a first graphite film facing the first housing wall and a second graphite film facing the conductor links, wherein a carrier film consisting of an electrically insulating material is provided between the graphite films. In this embodiment, the same applies mutatis mutandis to the second electrical insulation.

Particularly good thermomechanical properties are achieved by a preferred embodiment in which the first graphite film of the first and/or second electrical insulation extends beyond all of the conductor links assigned to the first or second housing walls. As an alternative to this, it is also conceivable for the first graphite film of the first and/or second electrical insulation to only extend sectionally beyond in each case one conductor link. Similarly, it has proven to be advantageous if the carrier film of the first and/or second electrical insulation extends beyond all of the conductor links assigned to the first and/or second housing wall. In an alternative variant to this, the carrier film of the first and/or second electrical insulation can also only extend sectionally beyond in each case one conductor link, however. Finally, it is also conceivable for the second graphite film of the first and/or second electrical insulation to be formed in such a way that it extends beyond all of the conductor links assigned to the first or second housing wall. As an alternative to this, it is again conceivable for the second graphite film of the first and/or second electrical insulation to only extend sectionally beyond in each case one conductor link.

In a preferred embodiment, the two graphite films and the carrier film are joined to the housing walls and the conductor links by means of heating, in particular by means of hot-pressing. Particularly preferably, the films are in this case heated to a temperature of over 500° C. and/or pressed against one another or onto the housing wall/the conductor links with a pressure of at least 2 N/mm². In this way, the thermal resistances between the housing walls and the conductor links can be minimized.

In another preferred embodiment, the first graphite film can have a film thickness of less than 1 mm, preferably of less than 0.5 mm. As an alternative or in addition, the second graphite film can have a film thickness of less than 1 mm, preferably of less than 0.5 mm. As an alternative or in addition to this, it is proposed that the carrier film is provided with a film thickness of less than 0.5 mm. These measures, either used individually or in combination, also result in a reduction in the thermal resistance.

Meanwhile, a further preferred embodiment in which the carrier film comprises or is a ceramic material can be produced with particularly low manufacturing costs.

In an advantageous development of this embodiment, it is proposed that aluminium oxide and/or aluminium nitride and/or silicon nitride and/or zirconium oxide is used as ceramic material so that the carrier film comprises one or more of these materials of consists of one of these materials. All of these materials have a high thermal conductivity, but are at the same time also electrically insulating, with the result that they are very well suited to use as an electrical insulator and thermal conductor in the first and second electrical insulation.

In another preferred embodiment, a metallization layer consisting of a metal, in particular of iron or silver or copper, can be applied to the first and/or second graphite film. This results in improved adhesion of the graphite films on the carrier film.

In order to improve the adhesion of the first graphite films to the housing walls, it is proposed that in each case one first adhesion-promoting layer is provided between the first graphite film and the first housing wall and/or between the first graphite film and the second housing wall. This adhesion-promoting layer can comprise, for example, an adhesive with a composition which changes chemically during heating or hot-pressing of the films.

In order to improve the adhesion of the second graphite films to the conductor links, it is correspondingly proposed that in each case one second adhesion-promoting layer is provided between the second graphite film and the respective conductor link. The second adhesion-promoting layer can also comprise an adhesive with a composition which changes chemically during heating or hot-pressing of the films.

In order to ensure the thermal insulation of the two housing walls acting as the hot and cold sides which is critical for the efficiency of the thermoelectric generator, it has proven to be advantageous to thermally insulate said housing walls from one another by means of a thermally insulating sealing element. In this context, an adhesive joint consisting of a thermally insulating adhesive or a sealing element consisting of an elastomer or another suitable plastic material should be borne in mind.

The invention furthermore relates to a method for producing a thermoelectric generator, in particular the thermoelectric generator proposed above. The method according to the invention comprises the following steps:
a) providing a housing, which delimits a housing interior and comprises a first housing wall and a second housing wall, which is opposite the first housing wall, wherein the two housing walls are thermally insulated from one another. One of the two housing walls acts as hot side of the thermoelectric generator, and the other housing wall acts as cold side. Preferably a metal such as aluminium, steel, nickel, copper or titanium, for example can be considered as the material for the housing.
b) providing a plurality of thermoelectric elements in the housing interior, which each comprise a thermoelectrically active material and are arranged spaced apart from one another in the housing interior, wherein two adjacent thermoelectric elements are connected to one another by means of an electrically conductive conductor link. Suitable thermoelectrically active materials are bismuth telluride and a skutterudite material, for example.
c) fastening the conductor links either by means of an electrically insulating first electrical insulation to an inner side, facing the housing interior, of the first housing wall or by means of an electrically insulating second electrical insulation to an inner side, facing the housing interior, of the second housing wall. The two electrical insulations in this case each comprise at least one graphite film, which graphite films are used, in interaction with a carrier film consisting of an electrically insulating material, as electrically insulating but thermally conductive interface between the conductor links of the thermoelectric elements and the housing walls.

In a further preferred embodiment, the fastening of the conductor links to the housing wall is performed by means of heating, in particular by means of hot-pressing, of the first and second electrical insulations so that said electrical insulation is joined both to the first or second housing wall and to the conductor links.

A particularly effective adhesive effect can be achieved if the joining of the two electrical insulations to the housing wall and the conductor links is performed in a common joining step.

Particularly expediently, the first and second electrical insulations each have a first graphite film, which faces the first or second housing wall, and a second graphite film, which faces the conductor links, wherein in each case one carrier film consisting of an electrically insulating material is arranged between the graphite films. The two graphite films and the carrier film are then joined to one another by means of heating, in particular by means of hot-pressing.

In order to improve the adhesive effect between the first graphite film and the first housing wall, it has proven to be advantageous to provide a first adhesion-promoting layer between the first graphite film and the first housing wall prior to the first electrical insulation and the first housing wall being joined to one another. This adhesion-promoting layer can comprise, for example, an adhesive which changes in particular its chemical composition during heating or hot-pressing. A corresponding first adhesion-promoting layer can be provided, mutatis mutandis, between the second electrical insulation and the second housing wall.

In order to improve the joining effect, the provision of a further, second adhesion-promoting layer between the respective second graphite film and the conductor links prior to the first electrical insulation and the conductor links being joined to one another is also proposed.

In order to further improve the adhesion properties of the two electrical insulations to the housing walls or conductor links, it is proposed that the at least one graphite film is metallized with a metal, in particular a metallization layer consisting of copper, silver or iron, prior to the joining process.

A particularly good adhesive effect can be achieved by virtue of the first graphite film and/or the second graphite film and/or the carrier film being roughened prior to the joining process.

Undesired contamination of the joint partners during the joining process can be largely or even completely excluded by virtue of the joint partners being joined to one another in an air or oxygen atmosphere.

Further important features and advantages of the invention are set forth in the dependent claims, in the drawings and in the associated description of the figures with reference to the drawings.

It goes without saying that the features mentioned above and yet to be explained below can be used not only in the respectively given combination, but also in other combinations or on their own without departing from the scope of the present invention.

Preferred exemplary embodiments of the invention are illustrated in the drawings and will be explained in more detail in the description below, wherein identical reference symbols relate to identical or similar or functionally identical components.

### BRIEF DESCRIPTION OF THE DRAWINGS

In the drawings, in each case schematically

FIG. 1 shows an example of a thermoelectric generator according to the invention in a longitudinal section,

FIG. 2 shows a first variant of the example in FIG. 1,

FIG. 3 shows a second variant of the example in FIG. 1.

### DETAILED DESCRIPTION

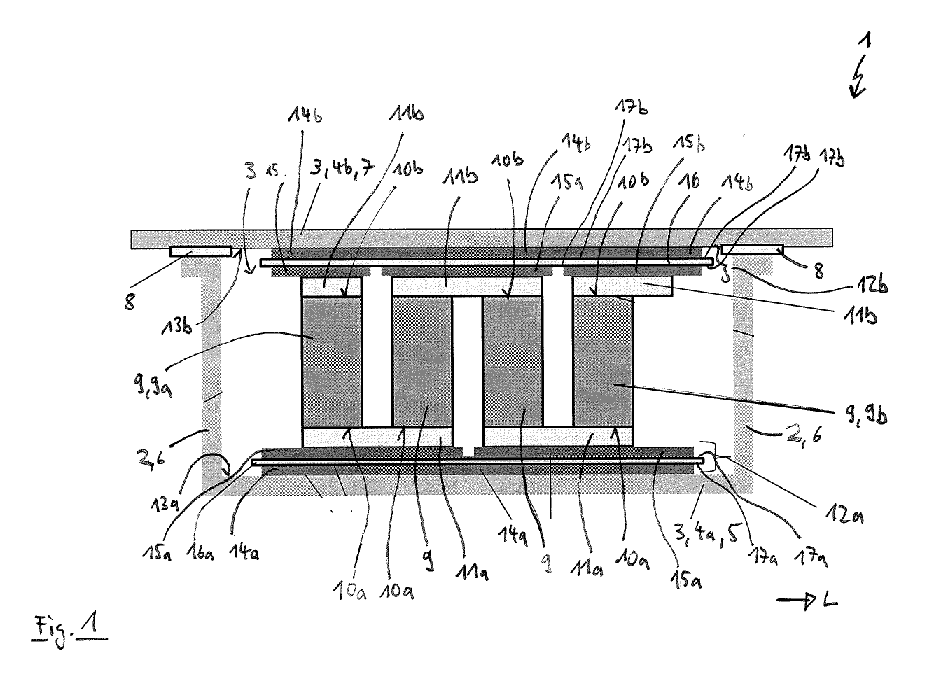

FIG. 1 illustrates, in a roughly schematic longitudinal section, an example of a thermoelectric generator 1 in accordance with the invention. Said thermoelectric generator has a sufficiently dimensioned housing 2 consisting of metal, for example of aluminium, steel, nickel, copper or titanium, which delimits a housing interior 3. The housing 2 comprises a first housing wall 4a and a second housing wall 4b, which is opposite the first housing wall 4a. One of the two housing walls 4a, 4b can be in the form of a housing pot having a pot base 5 and a pot collar 6 protruding from the pot base 5. In this example scenario, this is the first housing wall 4a. The second housing wall 4b is therefore in the form of a housing cover 7, which completes the housing pot to form the housing 2. The two housing walls 4a, 4b are thermally insulated from one another by means of a thermal insulation 8. The thermal insulation 8 can be embodied in the manner of a parting line consisting of an elastomer which follows the pot collar 6 and in particular is fluid-tight. However, an adhesive connection to a thermally insulating adhesive is also conceivable. Therefore, the first housing wall 4a can act as hot side and the second housing wall 4b can act as cold side of the thermoelectric generator 1, or vice versa.

Corresponding to the illustration in FIG. 1, a plurality of thermoelectric elements 9 which comprise a thermoelectrically active material are arranged spaced apart from one another in the housing interior 3. In this example scenario, the individual thermoelectric elements 9 are arranged substantially linearly along a longitudinal direction L of the housing 2 equidistantly from one another.

Bismuth telluride and a half Heusler or skutterudite material are examples of thermoelectrically active materials which are suitable for the thermoelectric elements 9.

With the exception of the two end-side, with respect to the longitudinal direction L, thermoelectric elements 9a, 9b, each thermoelectric element 9 is electrically connected, on its side 10a facing the first housing wall 4a, to the element 9 adjacent in the longitudinal direction L by means of an electrically conductive first conductor link 11a and is electrically connected, on its side 10b facing the second housing wall 4b, to the element 9 adjacent in the direction opposite to the longitudinal direction L by means of an electrically conductive conductor link 11b. In the example in FIG. 1, this is shown by way of example for four thermoelectric elements 9. The conductor links 11a, 11b can be produced from copper or nickel, for example.

Each of the first conductor links 11a is fastened to an inner side 13a, facing the housing interior 3, of the first housing wall 4a by means of an electrically insulating first electrical insulation 12a. In the same way, each of the second conductor links 11b is fastened to an inner side 13b, facing the housing interior 3, of the second housing wall 4b by means of an electrically insulating second electrical insulation 12b. Both the first and the second electrical insulation 12a, 12b each comprise at least one film consisting of graphite.

In the example scenario shown in FIG. 1, the first electrical insulation 12a comprises in each case one first graphite film 14a facing the first housing wall 4a and one second graphite film 15a facing the conductor links 11a. A carrier film 16a consisting of an electrically insulating material is provided between the graphite films 14a, 15a. Preferably, the material of the carrier film 16a is a ceramic. Possibilities for this are, for example, aluminium oxide, aluminium nitride, silicon nitride or zirconium oxide. The two graphite films 14a, 15a and the carrier film 16a arranged in the manner of a sandwich therebetween form a composite film. In a simplified variant, the first or second graphite film 14a, 15a can be dispensed with.

The second electrical insulation 12b comprises in each case one first graphite film 14b facing the second housing wall 4b and one second graphite film 15b facing the conductor links 11b. A carrier film 16b consisting of an electrically insulating material, in particular consisting of the abovementioned ceramic, is also provided between the graphite films 14b, 15b. The explanations in respect of the first electrical insulation 12a apply here analogously. The first graphite films 14a, 14b have, in this example, a film thickness of less than 1 mm, preferably of less than 0.5 mm. As an alternative or in addition, the second graphite films 15a, 15b can have a film thickness of less than 1 mm, preferably of less than 0.5 mm. The carrier films 16a, 16b have a film thickness of less than 0.5 mm.

As can be seen from FIG. 1, the two first graphite films 14a, 14b and the carrier films 16a, 16b extend beyond all of the conductor links 11a and 11b, respectively, assigned to the first and second housing walls 4a, 4b, respectively, i.e. only in each case one cohesive, first graphite film 14a, 14b and in each case one cohesive carrier film 16a, 16b is provided. In contrast, the second graphite films 15a, 15b only extend sectionally beyond all of the conductor links 11a and 11b, respectively, assigned to the first and second housing walls 4a, 4b, respectively. Therefore, in each case one individual second graphite film 15a, 15b is provided for each of the conductor links 11a, 11b. In this way, undesired thermomechanical stresses in the electrical insulations can be minimized.

A metallization layer 17a, 17b consisting of a metal, in particular of iron or silver or copper, can be applied to the first and/or second graphite film 14a, 14b, 15a, 15b (only indicated in FIG. 1). This results in improved adhesion of the graphite films 14a, 14b, 15a, 15b on the carrier film 16a, 16b. For reasons of clarity, a first adhesion-promoting layer provided between the first graphite film 14a and the first housing wall 4a and between the first graphite film 14b and the second housing wall 4b is not shown. An optional second adhesion-promoting layer (likewise not shown) is used, as an alternative or in addition to the first adhesion-promoting layer, for improving the adhesion of the electrical insulations 12a, 12b at the conductor links 11a, 11b. Both the first and the second adhesion-promoting layers can each comprise an adhesive with a composition which changes chemically during heating or hot-pressing of the films.

During production of the thermoelectric generator 1, the fastening of the conductor links 11a, 11b to the respective housing wall 4a, 4b is preferably performed by means of heating, in particular by means of hot-pressing, the first and second electrical insulations 12a, 12b. This takes place in such a way that said electrical insulations are joined both to the first or second housing wall 4a, 4b and to the conductor links 11a, 11b. Particularly good adhesion strength is achieved when the two electrical insulations 12a, 12b are joined to the housing wall 4a, 4b and the conductor links 11a, 11b in a common joining step.

The quality of the resultant adhesion joint can additionally be improved by virtue of the first graphite film and/or the second graphite film and/or the carrier film being roughened prior to being joined to one another. Impurities on the surfaces of the joint partners 4a, 4b, 11a, 11b, 14a, 14b, 15a, 15b, 16a, 16b which may reduce the adhesive connection can be largely or even completely avoided if the joining process is performed in an air or oxygen atmosphere.

A further measure which improves the adhesion of the joint partners 4a, 4b, 11a, 11b, 14a, 14b, 15a, 15b, 16a, 16b to one another can finally consist in metallizing the at least one graphite film 14a, 14b, 15a, 15b with a metal, in particular with a metallization layer consisting of copper, silver or iron, prior to the joining process.

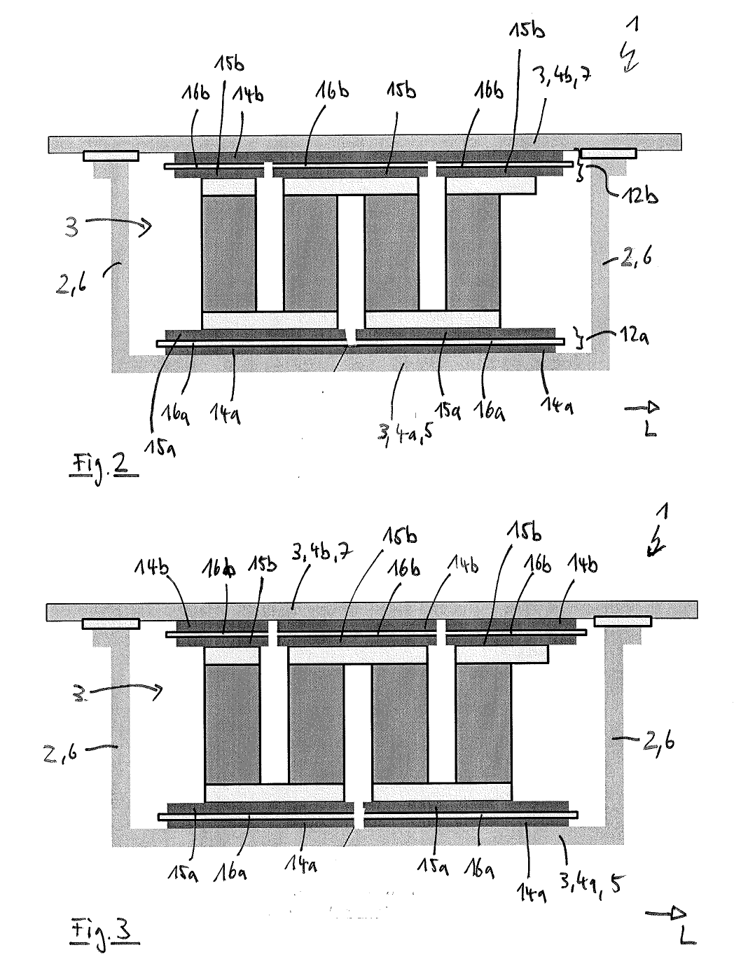

FIG. 2 shows a variant of the example in FIG. 1. The thermoelectric generator 1 in FIG. 2 differs from that in FIG. 1 in that, in the case of the former, the carrier films 16a, 16b of the first and/or second electrical insulation 12a, 12b, in the same way as the second graphite films 15a, 15b, only extend sectionally in each case beyond a conductor link 11a, 1 lb.

FIG. 3 again shows a variant of the example in FIG. 2. The thermoelectric generator 1 in FIG. 3 differs from that in FIG. 2 in that, in the case of the former, the first graphite films 14a, 14b of the first and/or second electrical insulation 12a, 12b, in the same way as the second graphite films 15a, 15b and the carrier films 16a, 16b, also only extend sectionally in each case beyond a conductor link 11a, 11b.

In the further variant (not illustrated in the figures) which can be combined with any of the variants in FIGS. 1 to 3, the pot collar 6 can be in the form of a thin-wall sheet-metal film. In this way, thermomechanical stresses between the two housing walls 4a, 4b acting as the hot or cold side can be suppressed particularly effectively.

In a further, simplified variant, it is conceivable for the two first graphite films 14a, 14b and the carrier films 16a, 16b to be replaced jointly by an electrically insulating coating, which is applied by means of thermal spraying to the housing walls 4a, 4b (not shown).

1. A thermoelectric generator comprising:
a housing delimiting a housing interior and having a first housing wall and a second housing wall opposite the first housing wall,
a plurality of thermoelectric elements each having a thermoelectrically active material and being arranged spaced apart from one another in the housing interior, wherein at least two adjacent thermoelectric elements are connected to one another by at least one electrically conductive conductor link,
wherein the at least one electrically conductive conductor link is fitted by at least one of an electrically insulating first electrical insulation on an inner side of the first housing wall facing the housing interior, and an electrically insulating second electrical insulation on an inner side, of the second housing wall facing the housing interior, and
wherein each of the at least one of a first and a second electrical insulation has at least one graphite film and at least one carrier film having an electrically insulating material.

2. A thermoelectric generator according to claim 1, wherein each of the at least one of a first and a second electrical insulation has a first graphite film facing at least one of the first and the second housing walls, and a second graphite film facing the at least one conductor link, wherein the at least one carrier film having an electrically insulating material is arranged between the first and the second graphite films.

3. A thermoelectric generator according to claim 2, wherein the two graphite films and the at least one carrier film are joined to the housing walls and to the conductor links by heating.

4. A thermoelectric generator according to claim 2, wherein:
at least one of the first graphite film, the at least one carrier film, and the second graphite film of the at least one of a first and a second electrical insulation extends beyond at least one of the at least one conductor links assigned to the at least one of the first and the second housing walls.

5. A thermoelectric generator according to claim 2, wherein at least one of:
(i) the first graphite film has a film thickness of less than 1 mm
(ii) the second graphite film has a film thickness of less than 1 mm, and
(iii) the at least one carrier film has a film thickness of less than 0.5 mm.

6. A thermoelectric generator according to claim 2, wherein the at least one carrier film includes a ceramic material.

7. A thermoelectric generator according to claim 6, wherein the ceramic material includes at least one of aluminium oxide, aluminium nitride, silicon nitride, and zirconium oxide.

8. A thermoelectric generator according to claim 2, wherein a metallization layer including a metal is applied to at least one of the first and second graphite film.

9. A thermoelectric generator according to claim 2, wherein a first adhesion-promoting layer is provided between the first graphite film and at least one of the first housing wall and the second housing wall.

10. A thermoelectric generator according to claim 9, wherein a second adhesion-promoting layer is provided between the second graphite film and the respective conductor link.

11. A thermoelectric generator according to claim 1, wherein the two housing walls are thermally insulated from one another by at least one of a thermally insulating sealing element and a thermally insulating adhesive bond, the thermally insulating sealing element including an elastomer.

12. A method for producing a thermoelectric generator, comprising:
providing a housing, which delimits a housing interior and includes a first housing wall and a second housing wall, which is opposite the first housing wall,
providing a plurality of thermoelectric elements in the housing interior, having a thermoelectrically active material and being arranged spaced apart from one another in the housing interior, wherein two adjacent thermoelectric elements are connected to one another by at least one electrically conductive conductor link, and
fastening the at least one conductor link by at least one of an electrically insulating first electrical insulation to an inner side of the first housing wall facing the housing interior, and an electrically insulating second electrical insulation to an inner side of the second housing wall facing the housing interior,
wherein each of the at least one of the first and the second electrical insulations each includes at least one graphite film.

13. A method according to claim 12, wherein the fastening of the conductor link to the housing wall is performed by heating the at least one of a first and a second electrical insulation so that said at least one of a first and a second electrical insulation is joined to at least one of the first and the second housing wall and to the at least one conductor link.

14. A method according to claim 12, wherein the joining of the at least one of a first and a second electrical insulation to the housing wall and to the conductor link is performed in a common joining step.

15. A method according to claim 12, wherein:
the at least one of a first and a second electrical insulation each has a first graphite film which faces at least one of the first and the second housing walls, respectively, and a second graphite film, which faces the conductor links, wherein at least one carrier film consisting of an electrically insulating material is arranged between the graphite films,
the first and the second graphite films and the at least one carrier film are joined to one another by heating.

16. A method according to claim 15, wherein at least one of:
a first adhesion-promoting layer is applied between the first graphite film and the first housing wall prior to the first electrical insulation and the first housing wall being joined to one another, and
a first adhesion-promoting layer is applied between the first graphite film and the second housing wall prior to the second electrical insulation and the second housing wall being joined to one another.

17. A method according to claim 16, wherein at least one of:
a second adhesion-promoting layer is applied between the second graphite film and the at least one conductor link prior to the first electrical insulation and the at least one conductor link being joined to one another, and/or
a second adhesion-promoting layer is applied between the second graphite film and the at least one conductor link prior to the second electrical insulation and the at least one conductor link being joined to one another.

18. A method according to claim 12, wherein the at least one graphite film is metallized, prior to the joining process, with a metal.

19. A method according to claim 15, wherein at least one of the first graphite film, the second graphite film, and the at least one carrier film are roughened prior to being joined to one another.

20. A method according to claim 12, wherein the joining process is performed in an air or oxygen atmosphere.
